(19) United States
(12) Patent Application Publication
(10) Pub. No.: US 2017/0208709 A1
(43) Pub. Date: Jul. 20, 2017

(54) SEALING AN INPUT/OUTPUT PORT OF AN INPUT/OUTPUT SWITCH

(71) Applicant: HEWLETT PACKARD ENTERPRISE DEVELOPMENT LP, Houston, TX (US)

(72) Inventor: John NORTON, Houston, TX (US)

(21) Appl. No.: 15/324,679

(22) PCT Filed: Jul. 18, 2014
(86) PCT No.: PCT/US2014/047130

§ 371 Date: Jan. 6, 2017

(51) Int. Cl. H05K 9/00; H05K 5/02

(52) U.S. Cl. CPC H05K 9/0018; H05K 5/0247

(57) ABSTRACT

A sealing device includes a seal member. The seal member includes a first end portion, a second end portion, and a main portion. The seal member flexes to move between a seal position to seal an input/output port of an input output switch and an unseal position to unseal the input/output port. The main portion includes a first shape when placed in the seal position in response to absence of a cable in the input/output port and a second shape when placed in the unseal position in response to placement of the cable in the input/output port.

### BACKGROUND

Input/output switches may be used in electrical systems such as server systems, and the like. The input/output switches include input/output ports to removably receive cables to transmit signals to the electrical systems. The input/output switches may also operate in a temperature-controlled environment and proximate to other electronic components.

### BRIEF DESCRIPTION OF THE DRAWINGS

Non-limiting examples are described in the following description, read with reference to the figures attached hereto and do not limit the scope of the claims. Dimensions of components and features illustrated in the figures are chosen primarily for convenience and clarity of presentation and are not necessarily to scale. Referring to the attached figures:

FIG. 1 is a block diagram illustrating a sealing device according to an example.

FIG. 2 is a perspective view illustrating a sealing device including a main portion having a first shape according to an example.

FIG. 3 is a perspective view illustrating a sealing device including a main portion having a second shape according to an example.

FIG. 4 is a block diagram illustrating an input/output switch according to an example.

FIG. 5 is a perspective view illustrating the input/output switch of FIG. 4 according to an example.

FIG. 6 is a cross-sectional view along line 6 of FIG. 5 illustrating a respective input/output port of the input/output switch in a seal position according to an example.

FIG. 7 is a cross-sectional view along line 7 of FIG. 5 illustrating a respective input/output port of the input/output switch in an unseal position according to an example.

FIG. 8 is a flowchart illustrating a method of sealing an input/output port of an input/output switch according to an example.

### DETAILED DESCRIPTION

Input/output switches include input/output ports to removably receive cables. Electromagnetic interference (EMI) may be emitted from the input/output ports. Further, airflow may also be emitted from the input/output ports and change the temperature of the input/output switches outside of a desired operating temperature range. Separate blanks may be used to manually seal the input/output ports to attempt to reduce EMI and airflow from being emitted from the input/output ports. Such sealing blanks, however, need to be manually inserted and removed from the input/output ports to seal and unseal it. The sealing blanks are also a separate component from the input/output switch. Thus, the sealing blanks require additional costs and manual labor to seal and unseal the input/output ports.

In examples, a sealing device includes a seal member. The seal member includes a first end portion, a second end portion, and a main portion. The seal member flexes to move between a seal position to seal an input/output port of an input output switch and an unseal position to unseal the input/output port. The main portion includes a first shape when placed in the seal position in response to an absence of a cable in the input/output port and a second shape when placed in the unseal position in response to placement of the cable in the input/output port. Thus, the seal member may be automatically placed in the seal position to reduce EMI emissions and airflow from the input/output ports in response to removal of the cable from the input/output port. Accordingly, interference of electronic components proximate to the input/output switches may be reduced and the input/output switches may maintain a desired operating temperature range in a cost-effective manner.

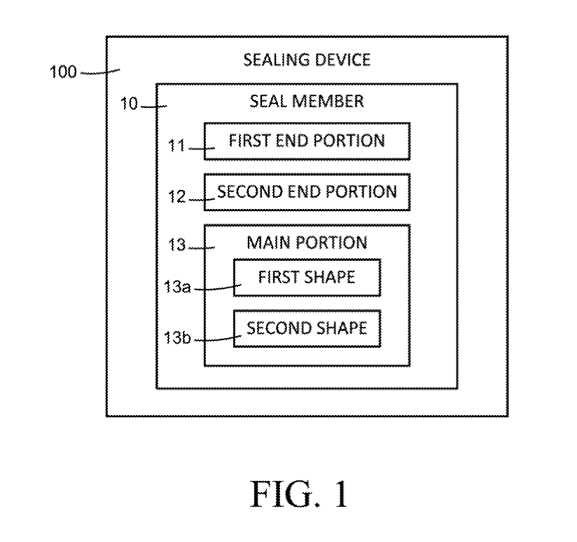

FIG. 1 is a block diagram illustrating a sealing device according to an example. The sealing device 100 may be usable with an input/output switch. The sealing device 100 includes a seal member 10. The seal member 10 flexes to move between a seal position and an unseal position. The seal member 10 includes a first end portion 11, a second end portion 12, and a main portion 13 disposed between the first end portion 11 and the second end portion 12. The first end portion 11 connects to the input/output port in the seal position and the unseal position. In the seal position, the seal member 10 seals an input/output port of the input output switch. For example, in the seal position, the seal member closes off the input/output port. In the unseal position, the seal member 10 unseals the input/output port. For example, in the unseal position, the seal member 10 opens up the input/output port.

Referring to FIG. 1, in some examples, the main portion 13 includes a first shape 13a and a second shape 13b. In the seal position, the main portion 13 exhibits the first shape 13a. In the unseal position, the main portion 13 exhibits the second shape 13b. The seal member 10 is placed in the seal position in response to an absence of a cable in the input/output port. For example, the cable may be manually inserted into the input/output port to electrically connect to the input/output switch. The input/output switch may be connected to an electrical system such, as a server system. The seal member 10 is placed in the unseal position in response to placement of the cable in the input/output port.

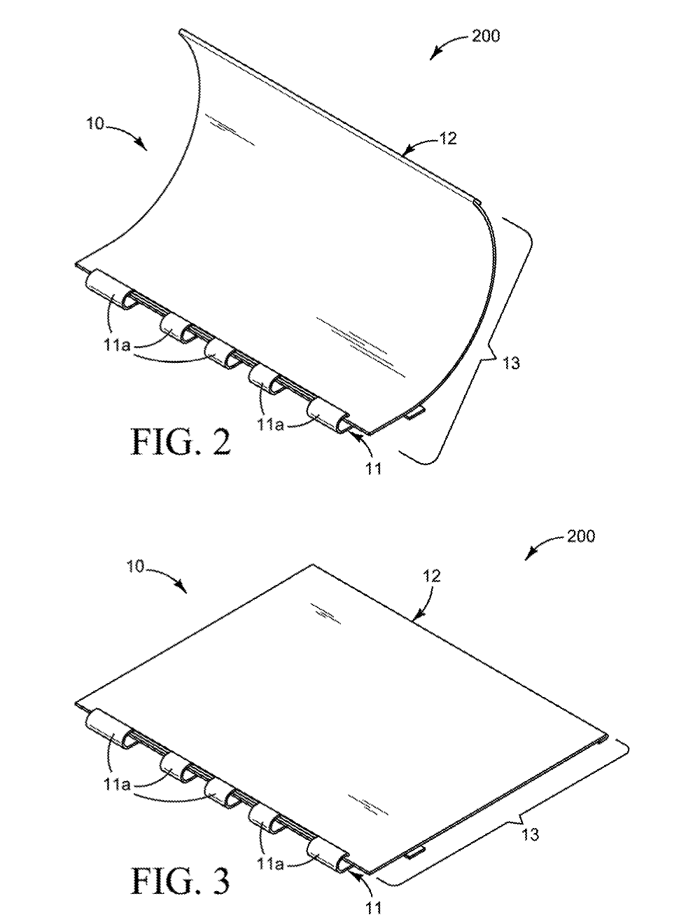

FIG. 2 is a perspective view illustrating a sealing device including a main portion having a first shape according to an example. FIG. 3 is a perspective view illustrating a sealing device including a main portion having a second shape according to an example. Referring to FIGS. 2-3, in some examples, the sealing device 200 includes the seal member 10 of the sealing device 100 previously discussed with respect to FIG. 1. In some examples, the seal member 10 is a single, unitary member formed, for example, of sheet metal. The seal member 10 includes a first end portion 11, a second end portion 12, and a main portion 13 disposed between the first end portion 11 and the second end portion 12.

Referring to FIGS. 2-3, in some examples, the first end portion 11 includes a plurality of spring fingers 11a. The spring fingers 11a may include shield fingers, grounding springs, and/or universal ground contacts to assist in reducing electromagnetic interference (EMI). The spring fingers 11a may include bent portions to couple to the input/output port. For example, the spring fingers 11a may be friction fitted and/or clipped to the input/output port. In some examples, the second end portion 12 includes an end folded onto itself 12a. The end folded onto itself may provide added strength and robustness to the second end 12. The second end portion 12 contacts the input/output switch in the seal position. For example, engagement of the second end portion 12 and an upper surface of the input/output port seal an interior region of the input/output port from an exterior region thereof. In some examples, the seal member 10 reduces an amount of EMI and airflow from passing out of the input/output port when placed in the seal position.

Additionally, the second end portion 12 separates from the input/output switch in the unseal position. For example, disengagement of the second end portion 12 from the upper surface of the input/output port unseals the input/output port and allows the cable to be received therein. That is, during insertion of the cable into the input/output port, the cable may push the seal member 10 out of the way. In some examples, the seal member 10 may be in contact with the cable in the unseal position. The seal member 10 may be disposed below the cable in the unseal position.

For example, the main portion 13 includes a first shape 13a when placed in the seal position in response to an absence of a cable in the input/output port. In some examples, the first shape 13a is curved. The main portion 13 includes a second shape 13b when placed in the unseal position in response to placement of the cable in the input/output port. That is, when the cable pushes against the seal member 10, a shape of the main portion 13 may change from the first shape 13a to the second shape 13b to allow the cable to be fully inserted into the input/output port. In some examples, the second shape is substantially flat.

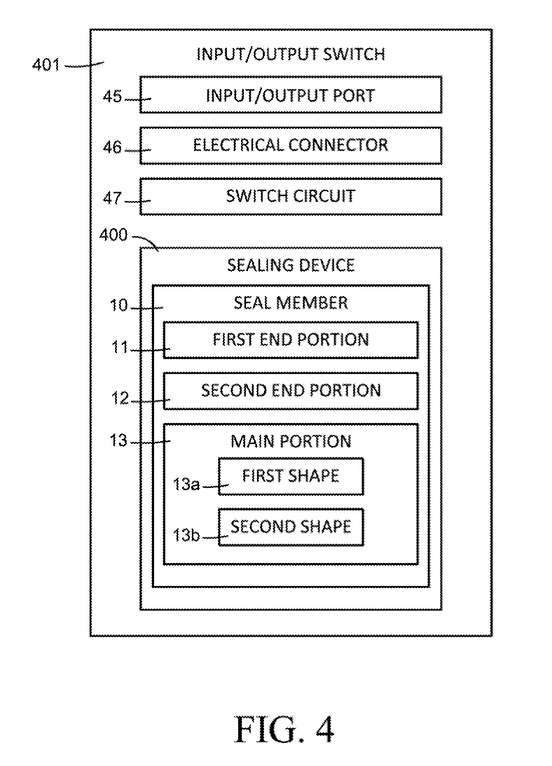

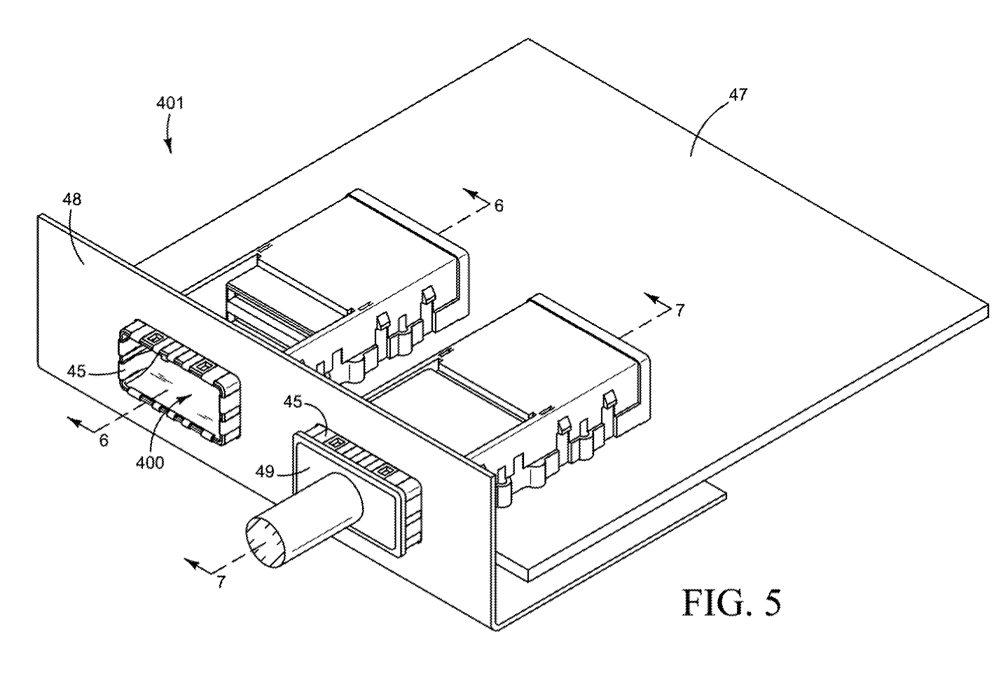

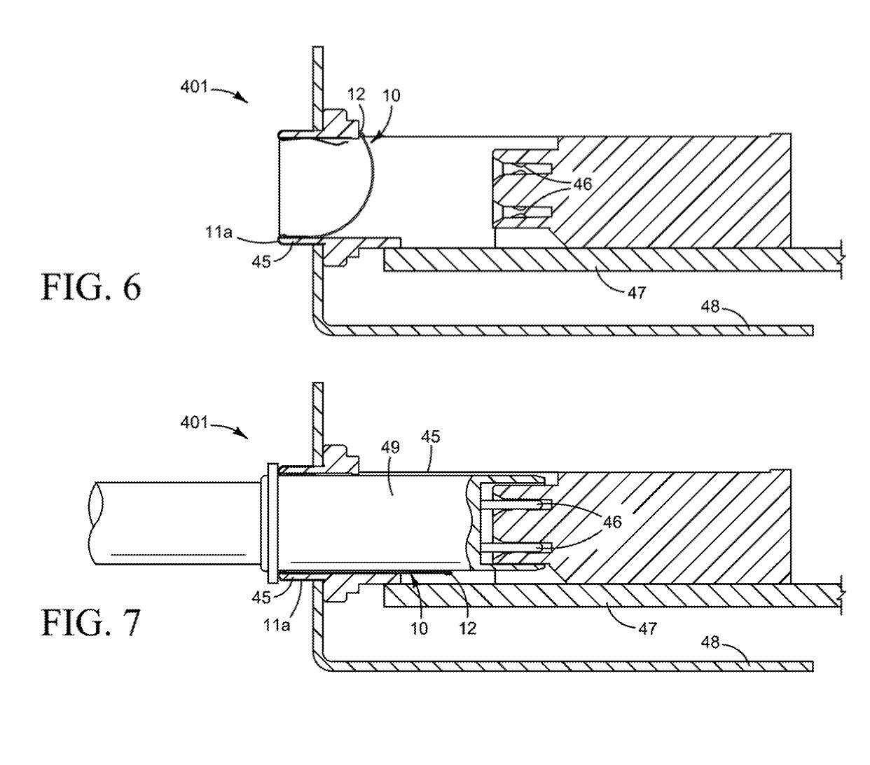

FIG. 4 is a block diagram illustrating an input/output switch according to an example. FIG. 5 is a perspective view illustrating an input/output switch according to an example. FIG. 6 is a cross-sectional view along line 6 of FIG. 5 illustrating a respective input/output port of the input/output switch of FIG. 5 in a seal position according to an example. FIG. 7 is a cross-sectional view along line 7 of FIG. 5 illustrating a respective input/output port of the input/output switch of FIG. 5 in an unseal position according to an example. Referring to FIGS. 4-8, the input/output switch 401 includes at least one input/output port 45, an electrical connector 46, a switch circuit 47, and a sealing device 400. The at least one input/output port 45 receives a cable 49. The electrical connector 46 is disposed within the input/output port 40 to connect to the cable 49. The switch circuit 47 processes signals. For example, the switch circuit 47 may include a printed circuit board. In some examples, the input/output switch 401 may also include a chassis 48 to couple to the input/output port 45 and the switch circuit 47.

Referring to FIGS. 4-7, in some examples, the sealing device 400 may include the seal member 10 as previously discussed with respect to FIGS. 1-5. In some examples, the sealing device 400 is movably coupled to the input/output port 45. The seal member 10 flexes to move between a seal position (FIG. 6) and an unseal position (FIG. 7). The seal member 10 includes a first end portion 11, a second end portion 12, and a main portion 13 disposed between the first end portion 11 and the second end portion 12. The first end portion 11 connects to the input/output port 45 in the seal position and the unseal position. In some examples, the first end portion 11 may include a plurality of spring fingers to connect to the input/output port in the seal position and the unseal position.

In the seal position, the seal member 10 seals an input/output port 45 of the input/output switch 401. For example, in the seal position, the seal member 10 doses off the input/output port 45. In the unseal position, the seal member 10 unseals the input/output port 45. For example, in the unseal position, the seal member 10 opens up the input/output port 45. The second end portion 12 may include an end folded onto itself to connect to the input/output switch 401 in the seal position and disconnect from the input/output switch 401 in the unseal position.

Referring to FIGS. 4-7, in some examples, the main portion 13 includes a first shape 13a such as a curved shape and a second shape 13b such as a substantially flat shape. In the seal position, the main portion 13 exhibits the first shape 13a. In the unseal position, the main portion 13 exhibits the second shape 13b. The seal member 10 is placed in the seal position in response to an absence of the cable 49 in the input/output port 45. For example, the cable 49 may be manually inserted into the input/output port 45 to electrically connect to the input/output switch 401. The input/output switch 401 may be connected to an electrical system such as a server system. The seal member 10 is placed in the unseal position in response to placement of the cable 49 in the input/output port 45.

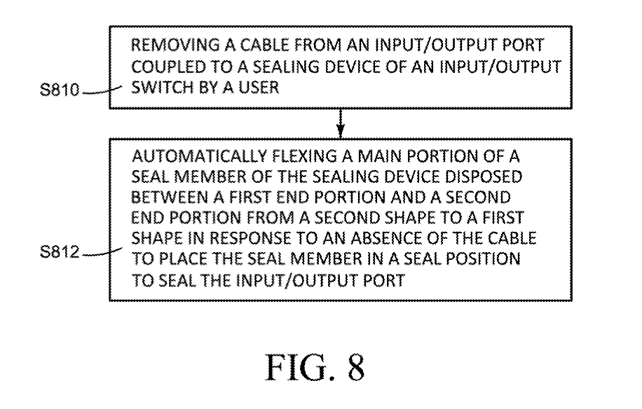

FIG. 8 is a flowchart illustrating a method of sealing an input/output port of an input/output switch according to an example. Referring to FIG. 8, in block S810, a cable is removed from an input/output port coupled to a sealing device of an input/output switch by a user. In block S812, a main portion of a seal member of the sealing device disposed between a first end portion and a second end portion automatically flexes from a second shape to a first shape in response to an absence of the cable to place the seal member in a seal position to seal the input/output port. For example, the first shape may be curved and the second shape may be substantially flat. The seal member may be conveniently coupled to the input/output port to automatically seal and unseal the input/output port in response to the insertion and removal of the cable with respect to the input/output port. In some examples, the first end portion includes a plurality of spring fingers to couple to the input/output port and reduce electromagnetic interference. Further, the sealing of the input/output port with the seal member may further reduce EMI and airflow from passing out of the input/output port.

It is to be understood that the flowchart of FIG. 8 illustrates architecture, functionality, and/or operation of examples of the present disclosure. If embodied in software, each block may represent a module, segment, or portion of code that includes one or more executable instructions to implement the specified logical function(s). If embodied in hardware, each block may represent a circuit or a number of interconnected circuits to implement the specified logical function(s). Although the flowchart of FIG. 8 illustrates a specific order of execution, the order of execution may differ from that which is depicted. For example, the order of execution of two, or more blocks may be rearranged relative to the order illustrated. Also, two or more blocks illustrated in succession in FIG. 8 may be executed concurrently or with partial concurrence. All such variations are within the scope of the present disclosure.

The present disclosure has been described using non-limiting detailed descriptions of examples thereof that are not intended to limit the scope of the general inventive concept. It should be understood that features and/or operations described with respect to one example may be used with other examples and that not all examples have all of the features and/or operations illustrated in a particular figure or described with respect to one of the examples. Variations of examples described will occur to persons of the art. Furthermore, the terms “comprise,” “include,” “have” and their conjugates, shall mean, when used in the disclosure and/or claims, “including but not necessarily limited to.”

It is noted that some of the above described examples may include structure, acts or details of structures and acts that may not be essential to the general inventive concept and which are described for illustrative purposes. Structure and acts described herein are replaceable by equivalents, which perform, the same function, even if the structure or acts are different, as known in the art. Therefore, the scope of the general inventive concept is limited only by the elements and limitations as used in the claims.

What is claimed is:

1. A sealing device usable with an input/output switch, the sealing device comprising:
a seal member including a first end portion, a second end portion, and a main portion disposed between the first end portion and the second end portion, the seal member to flex to move between a seal position to seal an input/output port of the input output switch and an unseal position to unseal the input/output port;
the main portion having a first shape when placed in the seal position in response to an absence of a cable in the input/output port and a second shape when placed in the unseal position in response to placement of the cable in the input/output port; and
the first end portion to connect to the input/output port in the seal position and the unseal position.

2. The sealing device of claim 1, wherein the first end portion comprises:
a plurality of spring fingers to couple to the input/output port and reduce electromagnetic interference.

3. The sealing device of claim 1, wherein the second end portion comprises an end folded onto itself to contact the input/output switch in the seal position and to separate from the input/output switch in the unseal position.

4. The sealing device of claim 1 wherein the first shape is curved and the second shape is substantially flat.

5. The sealing device of claim 1, wherein the seal member is a single, unitary member.

6. The sealing device of claim 1, wherein the seal member further comprises:
sheet metal.

7. The sealing device of claim 1, wherein the seal member reduces an amount of electromagnetic interference and airflow from passing out of the input/output port when placed in the seal position.

8. The sealing device of claim 1, wherein the seal member is in contact with the cable in the unseal position.

9. An input/output switch, comprising:
at least one input/output port to receive a cable:
an electrical connector disposed within the input/output port to removably connect to the cable;
a switch circuit to process signals; and
a sealing device movable coupled to the input/output port, the sealing device including:
a seal member including a first end portion, a second end portion, and a main portion disposed between the first end portion and the second end portion, the seal member to flex to move between a seal position to seal the input/output port and an unseal position to unseal the input/output port;
the main portion having a first shape when placed in the seal position in response to an absence of the cable in the input/output port and a second shape when placed in the unseal position in response to placement of he cable in the input/output port.

10. The input/output switch of claim 9, wherein the first end portion comprises a plurality of spring fingers to connect to the input/output port in the seal position and the unseal position, and the second end portion comprises an end folded onto itself to connect to the input/output switch in the seal position and disconnect from the input/output switch in the unseal position.

11. The input/output switch of claim 9, wherein the first shape is curved and the second shape is substantially flat.

12. The input/output switch of claim 9, wherein the seal member reduces an amount of electromagnetic interference and airflow from passing out of the input/output switch when placed in the seal position.

13. A method of sealing an input/output port of an input/output switch, the method comprising:
removing a cable from an input/output port coupled to a sealing device of an input/output switch by a user; and
automatically flexing a main portion of a seal member of the sealing device disposed between a first end portion and a second end portion from a second shape to a first shape in response to an absence of the cable to place the seal member in a seal position to seal the input/output port.

14. The method of claim 13, wherein the first shape is curved and the second shape is substantially flat.

15. The method of claim 13, wherein the first end portion comprises a plurality of spring fingers to couple to the input/output port and reduce electromagnetic interference.
